(19) United States
(12) Patent Application Publication
(10) Pub. No.: US 2026/0093179 A1
(43) Pub. Date: Apr. 2, 2026

(54) PHOTORESIST STRUCTURE, SEMICONDUCTOR DEVICE COMPRISING THE SAME, AND METHOD FOR FABRICATING THE SEMICONDUCTOR DEVICE COMPRISING THE SAME

(71) Applicant: NANYA TECHNOLOGY CORPORATION, NEW TAIPEI CITY (TW)

(72) Inventors: HAN-LIANG HUANG, NEW TAIPEI CITY (TW); TZU-YU CHOU, NEW TAIPEI CITY (TW)

(21) Appl. No.: 18/899,096

(22) Filed: Sep. 27, 2024

(51) Int. Cl. G03F 7/09; G03F 7/033

(52) U.S. Cl. CPC G03F 7/094; G03F 7/033

(57) ABSTRACT

The present application discloses a photoresist structure, a semiconductor device including the photoresist structure, and a method for fabricating the semiconductor device including the photoresist structure. The photoresist structure includes a bottom photoresist layer; a top photoresist layer positioned on the bottom photoresist layer. A coefficient of thermal expansion of the top photoresist layer is greater than a coefficient of thermal expansion of the bottom photoresist layer.

### TECHNICAL FIELD

The present disclosure relates to a photoresist structure, a semiconductor device including the photoresist structure, and a method for fabricating the semiconductor device with the photoresist structure.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a photoresist structure including a bottom photoresist layer; a top photoresist layer positioned on the bottom photoresist layer. A coefficient of thermal expansion of the top photoresist layer is greater than a coefficient of thermal expansion of the bottom photoresist layer.

One aspect of the present disclosure provides a semiconductor device including a substrate; an under layer; a bottom photoresist layer positioned on the under layer; a top photoresist layer positioned on the bottom photoresist layer; a recess positioned penetrating the top photoresist layer and the bottom photoresist layer and exposing the under layer; a spacer positioned within the recess and on sidewalls of the bottom photoresist layer and the top photoresist layer. The spacer includes a rectangular cross-sectional profile.

Another aspect of the present disclosure provides a method for fabricating a semiconductor device including providing a substrate, forming an under layer on the substrate, and forming a bottom photoresist layer on the under layer; forming a top photoresist layer on the bottom photoresist layer, wherein a coefficient of thermal expansion of the top photoresist layer is greater than a coefficient of thermal expansion of the bottom photoresist layer; performing an exposure process to form un-exposed portions and exposed portions of the bottom photoresist layer and the top photoresist layer; performing a post-exposure baking process to the bottom photoresist layer and the top photoresist layer; performing a developing process to remove the exposed portions of the bottom photoresist layer and the top photoresist layer and form a recess exposing the under layer; conformally forming a layer of spacer material on sidewalls of the top photoresist layer and the bottom photoresist layer, on a top surface of the top photoresist layer, and on a top surface of the under layer; performing a thermal treatment to expand the top photoresist layer; and performing an etching process to partially remove the layer of spacer material and form a spacer on the sidewalls of the top photoresist layer and the bottom photoresist layer.

The design of the semiconductor device described in this disclosure allows for an improved profile of the spacer by employing a top photoresist layer with a higher coefficient of thermal expansion (CTE). Consequently, the profile of the underlying layer, which is patterned using the spacer as a mask in subsequent processes, may also be enhanced, thereby reducing defects during the fabrication of the semiconductor device.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure;

FIG. 2 illustrates, in a schematic cross-sectional view diagram, an intermediate semiconductor device in accordance with one embodiment of the present disclosure;

FIG. 3 is a diagram showing illustrative components of a bottom photoresist layer in accordance with one embodiment of the present disclosure;

FIG. 4 is a diagram showing an illustrative polymer structure of a core polymer in accordance with one embodiment of the present disclosure;

FIG. 5 is a diagram showing an illustrative blocking structure of a blocking group in accordance with one embodiment of the present disclosure;

FIGS. 6 and 7 illustrate various characteristics of a sensitizer in accordance with one embodiment of the present disclosure;

FIGS. 8 and 9 show illustrative chemical structures of a photo acid generator in accordance with one embodiment of the present disclosure;

FIG. 10 illustrates, in a schematic cross-sectional view diagram, an intermediate semiconductor device in accordance with one embodiment of the present disclosure;

FIG. 11 is a diagram showing illustrative components of a top photoresist layer in accordance with one embodiment of the present disclosure; and

FIGS. 12 to 17 illustrate, in schematic cross-sectional view diagrams, part of the flow for fabricating the semiconductor device in accordance with one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

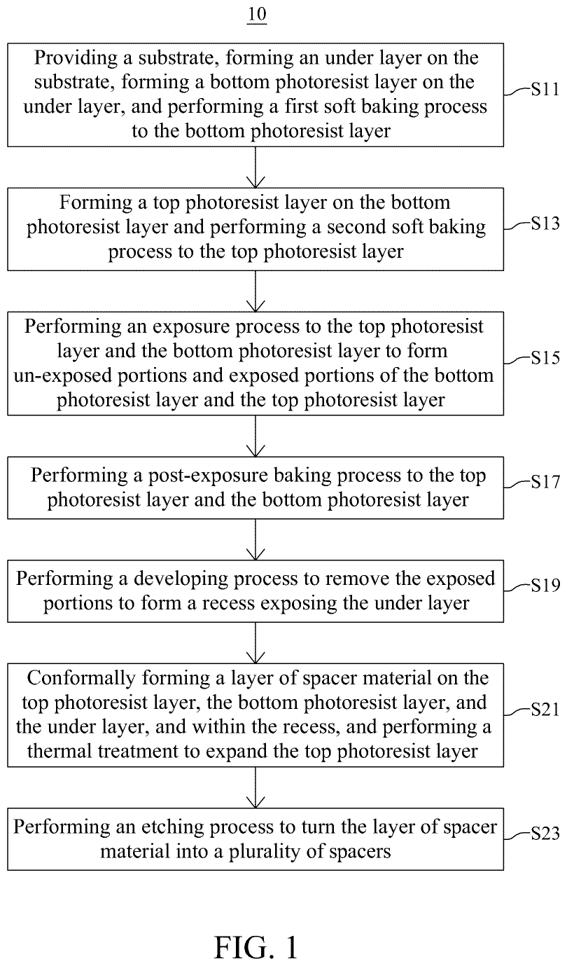

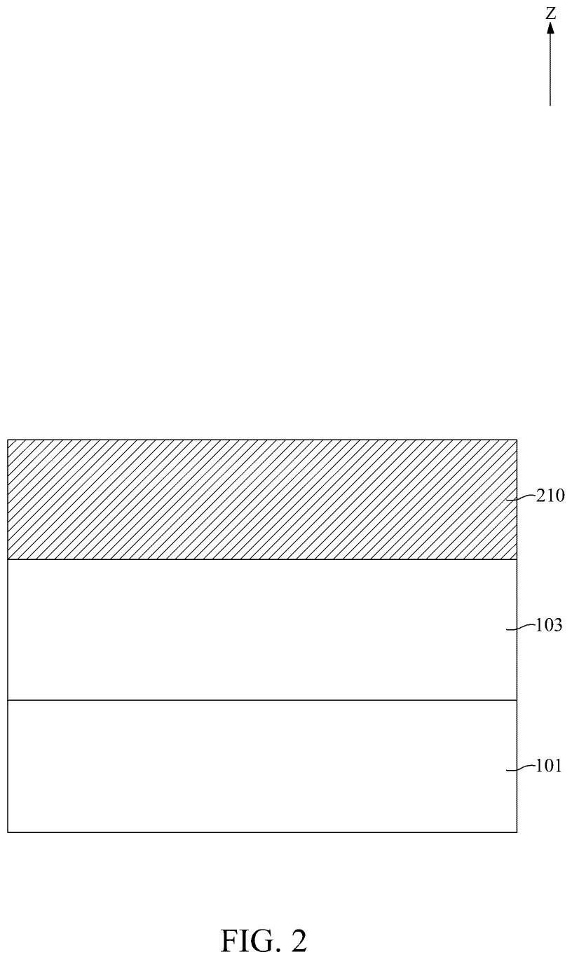

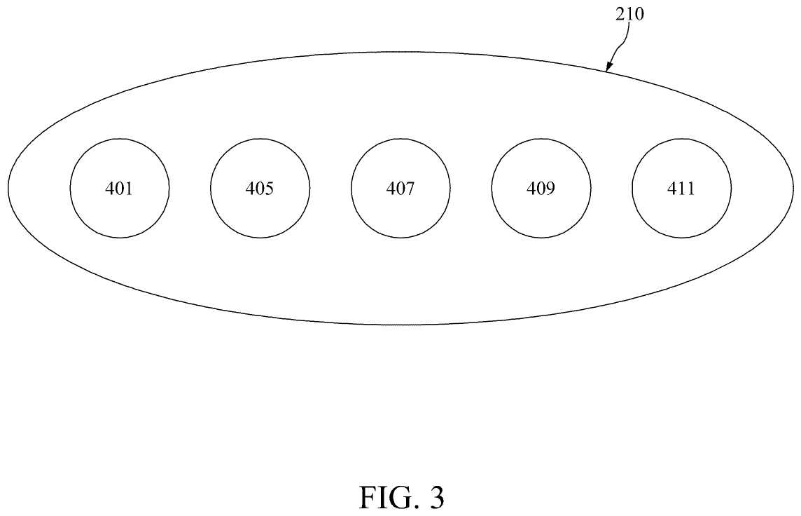

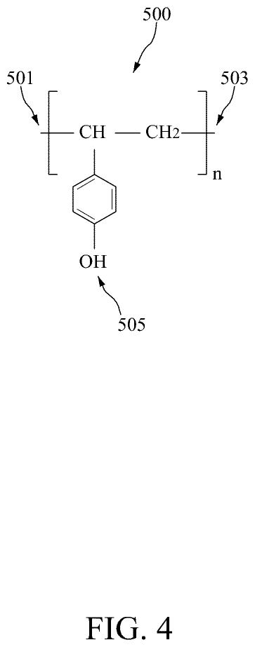

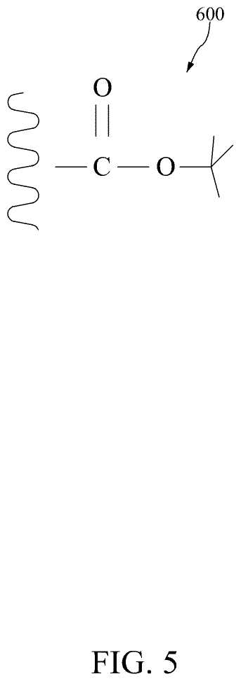

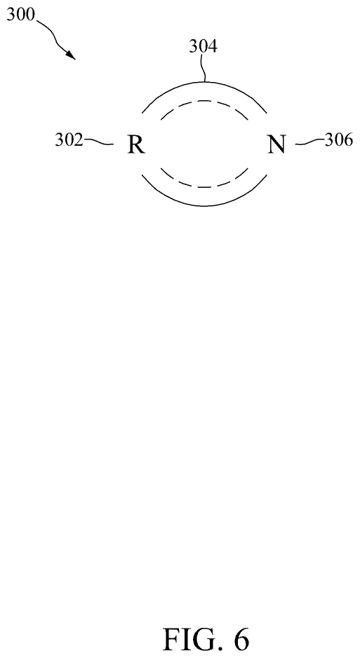

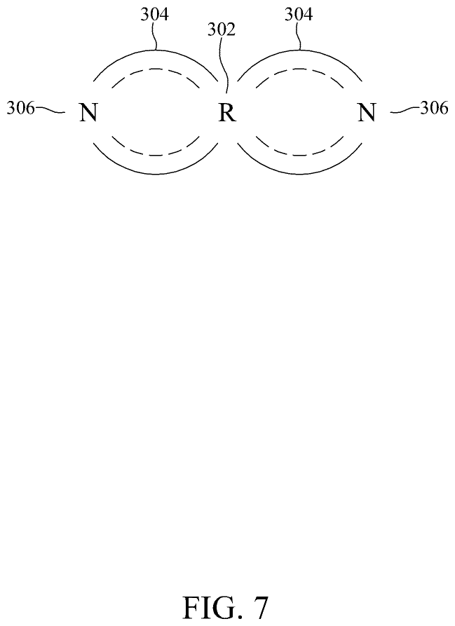

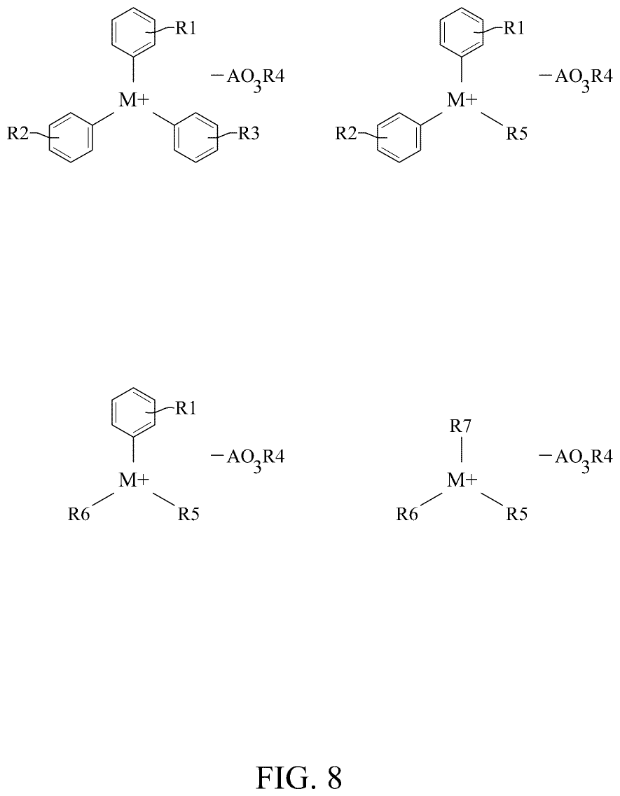

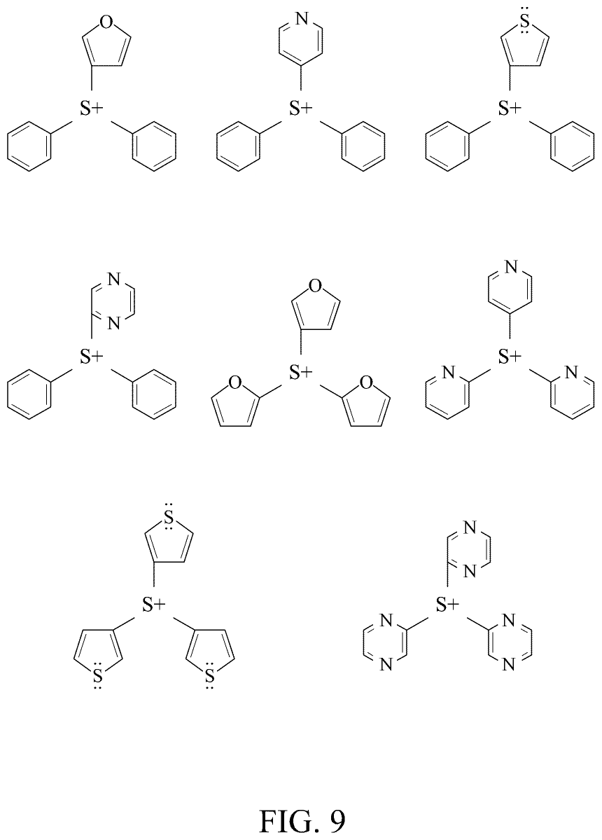

FIG. 1 illustrates, in a flowchart diagram form, a method 10 for fabricating a semiconductor device 1 in accordance with one embodiment of the present disclosure. FIG. 2 illustrates, in a schematic cross-sectional view diagram, an intermediate semiconductor device in accordance with one embodiment of the present disclosure. FIG. 3 is a diagram showing illustrative components of a bottom photoresist layer 210 in accordance with one embodiment of the present disclosure. FIG. 4 is a diagram showing an illustrative polymer structure of a core polymer 401 in accordance with one embodiment of the present disclosure. FIG. 5 is a diagram showing an illustrative blocking structure of a blocking group 405 in accordance with one embodiment of the present disclosure. FIGS. 6 and 7 illustrate various characteristics of a sensitizer 407 in accordance with one embodiment of the present disclosure. FIGS. 8 and 9 show illustrative chemical structures of a photo acid generator 409 in accordance with one embodiment of the present disclosure.

With reference to FIGS. 1 to 9, at step S11, a substrate 101 may be provided, an under layer 103 may be formed on the substrate 101, a bottom photoresist layer 210 may be formed on the under layer 103, and a first soft baking process may be performed to the bottom photoresist layer 210.

With reference to FIG. 2, in some embodiments, the substrate 101 may be a silicon substrate doped with a p-type dopant such as boron (for example a p-type substrate). In some embodiments, the substrate 101 may be another suitable semiconductor material. For example, the substrate 101 may be a silicon substrate that is doped with an n-type dopant such as phosphorous or arsenic (an n-type substrate). In some embodiments, the substrate 101 may include other elementary semiconductors such as germanium and diamond. In some embodiments, the substrate 101 may optionally include a compound semiconductor and/or an alloy semiconductor. In some embodiments, the substrate 101 may include an epitaxial layer (epi layer), may be strained for performance enhancement, and may include a silicon-on-insulator (SOI) structure.

In some embodiments, the substrate 101 may be substantially conductive or semi-conductive. The electrical resistance may be less than about 10³ ohm-meter. In some embodiments, the substrate 101 may contain metal, metal alloy, or metal nitride/sulfide/selenide/oxide/silicide with the formula MXₐ, where M is a metal, and X is N, S, Se, O, Si, and where “a” is in a range from about 0.4 to 2.5. For example, the substrate 101 may contain Ti, Al, Co, Ru, TiN, WN₂, or TaN.

In some embodiments, the substrate 101 may contain a dielectric material with a dielectric constant in a range from about 1 to about 40. In some embodiments, the substrate 101 may contain Si, metal oxide, or metal nitride, where the formula is MX_{b}, wherein M is a metal or Si, and X is N or O, and wherein “b” is in a range from about 0.4 to 2.5. For example, the substrate 101 may contain silicon oxide, silicon nitride, aluminum oxide, hafnium oxide, or lanthanum oxide.

With reference to FIG. 2, the under layer 103 may be formed on the substrate 101. In some embodiments, the under layer 103 may be a layer to be patterned during the following processes. In some embodiments, the under layer 103 may include material(s) such as silicon oxide, silicon nitride, silicon oxynitride, or other suitable material or composition. In some embodiments, the under layer 103 may be an anti-reflection coating layer such as a nitrogen-free anti-reflection coating layer including material(s) such as silicon oxide, silicon oxygen carbide, or plasma enhanced chemical vapor deposited silicon oxide. In some embodiments, the under layer 103 may include a high-k dielectric layer, a gate layer, a hard mask layer, an interfacial layer, a capping layer, a diffusion/barrier layer, a dielectric layer, a conductive layer, other suitable layers, and/or combinations thereof. In some embodiments, the under layer 103 may be formed by a deposition process including, for example, chemical vapor deposition, plasma enhanced chemical vapor deposition, physical vapor deposition, evaporation, electroplating, electroless plating, or spin-on coating.

In some embodiments, the bottom photoresist layer 210 may be formed on the under layer 103. In some embodiments, the bottom photoresist layer 210 may be a chemically amplified resist. In some embodiments, the bottom photoresist layer 210 may be positive tone or negative tone. In some embodiments, the bottom photoresist layer 210 may be formed by a spin-on coating process. In some embodiments, the bottom photoresist layer 210 may be sensitive to a radiation, such as I-line light, a deep ultraviolet (DUV) light (e.g., 248 nm radiation by krypton fluoride (KrF) excimer laser or 193 nm radiation by argon fluoride (ArF) excimer laser), an extreme ultraviolet (EUV) light (e.g., 135 nm light), an electron beam (e-beam), and an ion beam.

With reference to FIG. 3, in some embodiments, the bottom photoresist layer 210 may include a core polymer 401, a blocking group 405 chemically bonded to the polymer 401, a sensitizer 407, a photo acid generator (PAG) 409, and a solvent 411.

In some embodiments, the core polymer 401 may provide resistance to etch (or implantation). In some embodiments, the core polymer 401 may include a poly(norbornene)-co-malaic anhydride (COMA) polymer, a polyhydroxystyrene (PHS) polymer, or an acrylate-based polymer. For example, the acrylate-based polymer includes a poly (methyl methacrylate) (PMMA) polymer. The PHS polymer includes a plurality of PHS chemical structure 500 as shown in FIG. 4, in which n is an integer greater than 2. The PHS chemical structure 500 includes two ends 501 and 503 that are chemically linkable ends of other PHS chemical structures. The PHS is sensitive to EUV and is able to function as a sensitizer during an exposure process. Accordingly, a plurality of the PHS chemical structures 500 are chemically bonded together (through the two ends 501 and 503), thereby forming a PHS polymeric backbone. The core polymer 401 may also include multiple side locations that may chemically bond with other chemical groups. For example, the PHS polymer includes a plurality of hydroxyl (OH) groups 505 chemically bonded to side locations.

In some examples, the blocking group 405 may be an acid labile group (ALG) or dissolution inhibitor that responds to acid. In some embodiments, the blocking group 405 may be a chemical group that is deprotected by photoacid generator in exposed regions of the bottom photoresist layer 210. Thus, the exposed bottom photoresist layer 210 will change the polarity and dissolubility. For example, the exposed bottom photoresist layer 210 may have an increased dissolubility in a developer (for a positive-tone bottom photoresist layer 210) or decreased dissolubility in a developer (for a negative-tone bottom photoresist layer 210). When the exposing dose of the lithography exposing process reaches a dose threshold, the exposed bottom photoresist layer 210 will be dissoluble in the developer or alternatively the exposed bottom photoresist layer 210 will be insoluble in the developer. In some embodiments, the blocking group 405 may include a t-butoxy-cardbonyl group 600 illustrated in FIG. 5.

In some embodiments, the sensitizer 407 may increase the sensitivity and efficiency of the bottom photoresist layer 210. In some embodiments, the sensitizer 407 may be designed to increase the sensitivity of the bottom photoresist layer 210. By incorporating the bottom photoresist layer 210, the bottom photoresist layer 210 may have an enhanced sensitivity to the first radiation. Detailedly, the sensitizer 407 may be sensitive to the first radiation and be able to generate a second radiation in response to the first radiation. In the present embodiment, the first radiation is EUV radiation, and the second radiation is electron(s). The sensitizer 407 absorbs EUV radiation and generates secondary electrons. Furthermore, the photo acid generator 409 may be sensitive to the secondary electron, absorbs the secondary electron and generates acid.

In some embodiments, the sensitizer 407 may be mixed with the core polymer 401 and the photo acid generator 409 in the solvent 411. In some embodiments, the sensitizer 407 may be alternatively or additionally bonded to the core polymer 401 or the photo acid generator 409. In some embodiments, the sensitizer 407 may be monomer additive, oligomer and polymer type in the bottom photoresist layer 210.

In some embodiments, the sensitizer 407 may include a heterocyclic ring that includes at least one nitrogen atom and at least one double bond. In some embodiments, the sensitizer 407 may have a recombination energy within a range of about 165-170 kilocalories/mol. FIGS. 6 and 7 illustrate various double bonds 304 between a nitrogen atom 306 and R 302, which may be a C4^{˜}C30 resonance ring, aromatic, or heterocyclic aromatic. R 302 may also contain a polar group such as —OH, —NH₂, —COOH, —CONH₂. Such a structure provides the sensitizer 407 with a lower ionization energy and higher recombination energy. FIG. 6 illustrates an example in which there is one nitrogen atom bonded to a resonance ring. FIG. 7 illustrates an example in which there are two nitrogen atoms bonded to a resonance ring.

In some embodiments, the photo acid generator 409 (also referred to as an acid generating compound, AGC) can absorb radiation energy and generate acid. In some embodiments, the photo acid generator 409 may include a phenyl ring. For example, the photo acid generator 409 may include a sulfonium cation, such as a triphenylsulfonium (TPS) group; and an anion, such as a triflate anion. The cation of the photo acid generator 409 may have a chemical bond to a sulfur and an additional chemical bond such that the sensitivity (or absorption) of the photo acid generator 409 to the electron, or other type of the second radiation, is increased.

In some embodiments, the photo acid generator 409 may be designed with chemical structure to effectively absorb EUV radiation. For example, the photo acid generator 409 may include fluorine, saturated alkyl group, aromatics, heterocyclic group or a combination to enhance the EUV absorption. In some examples, the sensitizer 407 may be chemically bonded to the photo acid generator 409.

In some embodiments, the photo acid generator 409 may be designed to have specific chemical structures to better absorb electrons generated by the sensitizer 407. In some embodiments, the photo acid generator 409 may include at least one heterocyclic ring having at least one nitrogen or oxygen atom in addition to several carbon atoms. In some embodiments, the photo acid generator 409 may also have at least one double bond within that heterocyclic ring. Various examples of the photo acid generator 409 are shown in FIGS. 8 and 9.

FIG. 8 illustrates the photo acid generator 409 that has a structure M+ that is surrounded by a number of heterocyclic structures. Such heterocyclic structures are indicated by R1, R2, R3, R4, R5, R6, and R7. R1, R2, R3, R4, R5, R6, and R7 may include at least one of C1^{˜}C20 heterocyclic aromatics derivatives (e.g., Furan, Pyridine, Pyrazine, Imidazole, thiophene) and fluoro alkyl groups. In some examples, M may be a cation and A may be an anion. In some examples, M or A may be one of Sulfur, Carbon, or Iodine.

FIG. 9 illustrates the photo acid generator 409 that has a structure surrounded by a number of rings. In the present embodiment, the structure is a sulfur cation. As illustrated, each structure has at least one heterocyclic ring with at least one double bond. In some examples, there are at least two double bonds. In some examples, there are three double bonds.

After the bottom photoresist layer 210 is formed, the first soft baking process may be performed to the bottom photoresist layer 210 to reduce the solvent in the bottom photoresist layer 210. For example, the solvent 411 may be partially evaporated by the first baking process.

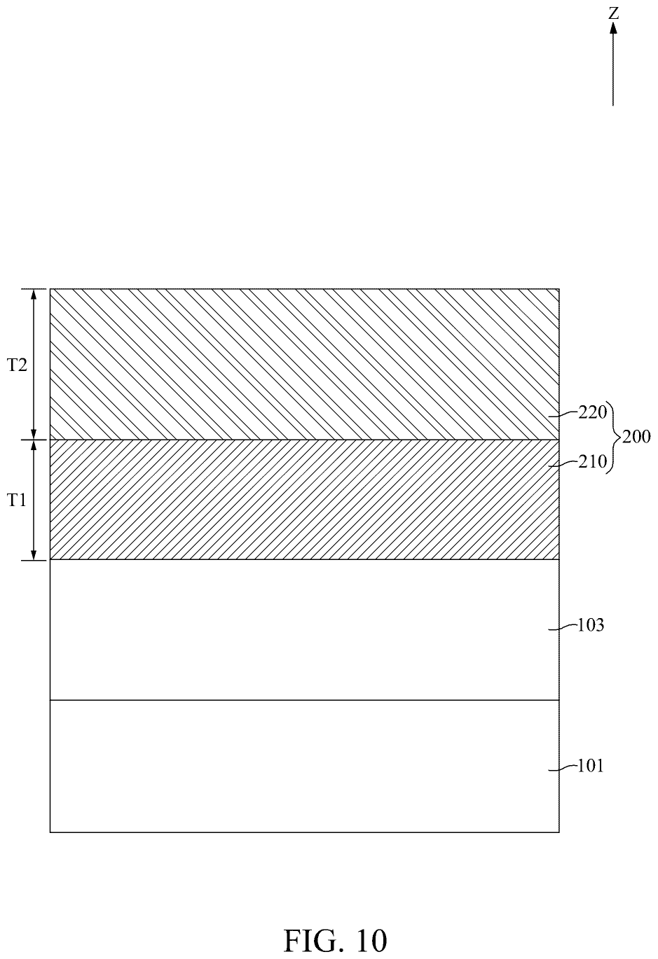

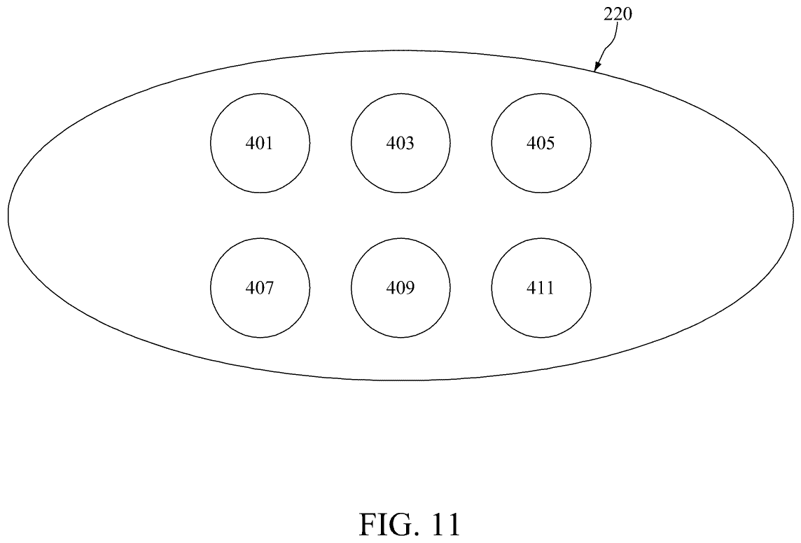

FIG. 10 illustrates, in a schematic cross-sectional view diagram, an intermediate semiconductor device in accordance with one embodiment of the present disclosure. FIG. 11 is a diagram showing illustrative components of a top photoresist layer 220 in accordance with one embodiment of the present disclosure.

With reference to FIGS. 1, 10, and 11, at step S13, a top photoresist layer 220 may be formed on the bottom photoresist layer 210 and a second soft baking process may be performed to the top photoresist layer 220.

With reference to FIG. 10, the top photoresist layer 220 may be formed on the bottom photoresist layer 210 by a spin-on coating process. The top photoresist layer 220 and the bottom photoresist layer 210 may together configure a photoresist structure 200. In some embodiments, the top photoresist layer 220 may be a chemically amplified resist. In some embodiments, the top photoresist layer 220 may be positive tone or negative tone. It should be noted that the type of the bottom photoresist layer 210 and the top photoresist layer 220 are the same. That is, the bottom photoresist layer 210 and the top photoresist layer 220 both are positive tone, or both are negative tone.

In some embodiments, the top photoresist layer 220 may be sensitive to a radiation, such as I-line light, a DUV light (e.g., 248 nm radiation by KrF excimer laser or 193 nm radiation by ArF excimer laser), a EUV light (e.g., 135 nm light), a e-beam, and an ion beam.

In some embodiments, the top photoresist layer 220 and the bottom photoresist layer 210 may have different coefficients of thermal expansion (CTE). In some embodiments, the CTE of the top photoresist layer 220 may be greater than the CTE of the bottom photoresist layer 210. In some embodiments, the ratio of the CTE of the top photoresist layer 220 to the CTE of the bottom photoresist layer 210 may be between about 2.0 and about 1.1, between about 1.5 and about 1.1, or between about 1.3 and about 1.1.

The difference in CTE between top photoresist layer 220 and the bottom photoresist layer 210 can be attributed to several factors related to their compositional and structural differences. In some embodiments, the difference in CTE may be caused by different chain length or different structure of polymers of the photoresist layers. In some embodiments, the difference in CTE may be caused by different composition of polymers of the photoresist layers. In some embodiments, the difference in CTE may be caused by different thicknesses of photoresist layers.

In some embodiments, the top photoresist layer 220 may contain polymers with longer, more flexible chains compared to the bottom photoresist layer 210. This increased chain flexibility allows for greater molecular motion under thermal expansion, resulting in a higher CTE. In contrast, the bottom photoresist layer 210 may have a more rigid polymer backbone, limiting chain movement and consequently exhibiting a lower CTE.

The strength of intermolecular forces between polymer chains can significantly influence CTE. In some embodiments, the top photoresist layer 220 may have weaker intermolecular interactions, such as van der Waals forces, allowing for easier chain movement during thermal expansion. On the other hand, the bottom photoresist layer 210 may exhibit stronger intermolecular forces, like hydrogen bonding, restricting chain mobility and leading to a lower CTE. In some embodiments, the top photoresist layer 220 may include a polymer having ester groups and/or ether groups which may reduce chain stiffness. As a result, the strength of intermolecular forces between polymer chains may be reduced.

The presence of thermally expansive functional groups within the polymer structure of the photoresist layer can contribute to a higher CTE. In some embodiments, the top photoresist layer 220 may contain functional groups that undergo significant volumetric expansion upon heating, amplifying the overall CTE of the material. The bottom photoresist layer 210, lacking such groups, may exhibit a lower CTE. In some embodiments, the top photoresist layer 220 may include thermally functional groups such as benzene rings, polycyclic aromatic hydrocarbons (e.g., naphthalene), heterocyclic rings, cyclohexane, long alkyl chains, branched alkyl chains, or a combination thereof.

In some embodiments, the composition of the top photoresist layer 220 may be the same as the bottom photoresist layer 210. That is, the top photoresist layer 220 may include the core polymer 401, the blocking group 405 chemically bonded to the polymer 401, the sensitizer 407, the photo acid generator 409, and the solvent 411, and descriptions thereof are not repeated herein. In some embodiments, the thickness T2 of the top photoresist layer 220 may be greater than the thickness T1 of the bottom photoresist layer 210. In some embodiments, the chain length of the core polymer 401 of the top photoresist layer 220 may be greater than the chain length of the core polymer 401 of the bottom photoresist layer 210.

In some embodiments, the core polymer 401 of the top photoresist layer 220 may include more thermally expansive functional groups than that of the core polymer 401 of the bottom photoresist layer 210.

In some embodiments, the core polymer 401 of the top photoresist layer 220 may include more ester groups and/or ether groups than that of the core polymer 401 of the bottom photoresist layer 210.

In some embodiments, the composition of the top photoresist layer 220 and the composition of the bottom photoresist layer 210 may be different. In some embodiments, the top photoresist layer 220 may further include an adjusting polymer 403. The adjusting polymer 403 may be a higher thermal expansion polymer which can increase the CTE of the top photoresist layer 220. In some embodiments, the adjusting polymer 403 may include, for example, elastomers (e.g., as polybutadiene, polyisoprene, and styrene-butadiene rubber), thermoplastic elastomers (e.g., styrene-ethylene-butadiene-styrene and thermoplastic polyurethane), and/or liquid crystal polymers. In some embodiments, the weight ratio of the adjusting polymer 403 to the core polymer 401 of the top photoresist layer 220 may be between about 20% and about 0.1%, between about 15% and about 0.1%, between about 10% and about 0.1%, between about 5.0% and 0.1%, between about 3.0% and about 0.1%, or between about 1% and about 0.1%.

After the top photoresist layer 220 is formed, the second baking process may be performed to the top photoresist layer 220 to reduce the solvent in the top photoresist layer 220. For example, the solvent 411 may be partially evaporated by the second baking process.

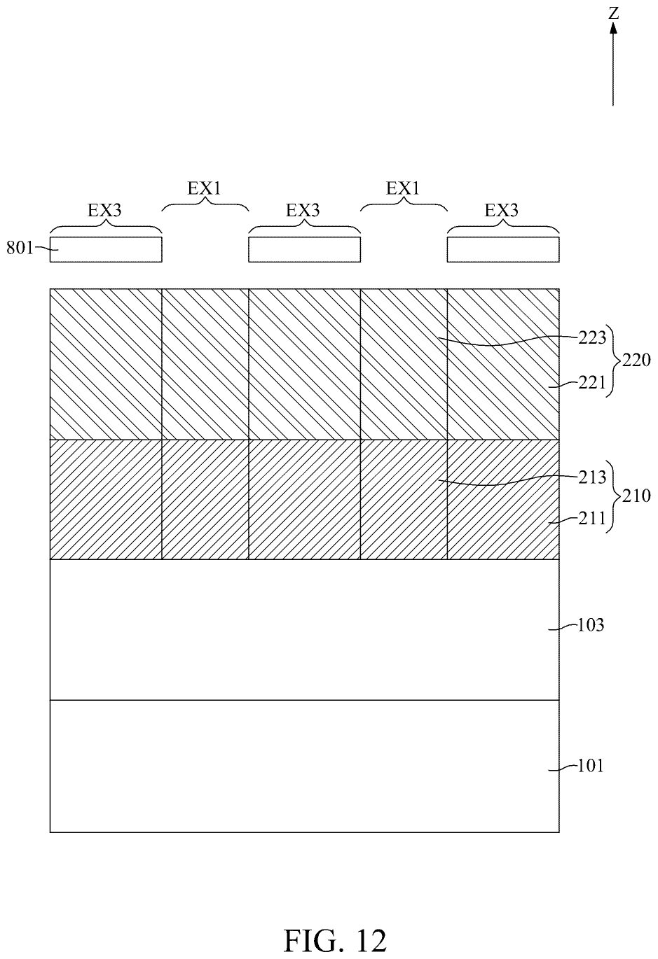

FIGS. 12 to 17 illustrate, in schematic cross-sectional view diagrams, part of the flow for fabricating the semiconductor device 1 in accordance with one embodiment of the present disclosure.

With reference to FIGS. 1 and 12, at step S15, an exposure process may be performed to the top photoresist layer 220 and the bottom photoresist layer 210 to form un-exposed portions 211, 221 and exposed portions 213, 223 of the bottom photoresist layer 210 and the top photoresist layer 220.

With reference to FIG. 12, the exposure process may be performed to expose the photoresist layer 58 through a mask 801 by using a radiation such that the bottom photoresist layer 210 may have an exposed portion 213 (under the exposed region EX1) and an un-exposed portion 211 (under the un-exposed region EX3), and the top photoresist layer 220 may have an exposed portion 223 (under the exposed region EX1) and an un-exposed portion 221 (under the un-exposed region EX3). The mask 801 has a plurality of transparent regions through which the radiation transmits to the top photoresist layer 220 and the bottom photoresist layer 210. In some embodiments, as the top photoresist layer 220 and the bottom photoresist layer 210 are illuminated by the radiation, the photo acid generators 409 in the top photoresist layer 220 and the bottom photoresist layer 210 may produce acids, which release protons (H⁺). The released protons react with the hydrophobic acid labile groups of the top photoresist layer 220 and the bottom photoresist layer 210 so as to convert the hydrophobic acid labile groups into hydrophilic groups.

In some embodiments, the radiation may be an EUV radiation (e.g., 13.5 nm). In some embodiments, the radiation may be an I-line (365 nm), a DUV radiation such as KrF excimer laser (248 nm), ArF excimer laser (193 nm), a EUV radiation, an x-ray, an e-beam, an ion beam, and/or other suitable radiations. In some embodiments, the exposure process may be performed in air, in a liquid (immersion lithography), or in a vacuum (e.g., for EUV lithography and e-beam lithography).

In some embodiments, various resolution enhancement techniques, such as phase-shifting, off-axis illumination (OAI) and/or optical proximity correction (OPC), may be implemented through the mask 801 or the exposure process. For example, the OPC features may be incorporated into the circuit pattern. In another example, the mask 801 may be a phase-shift mask, such as an alternative phase-shift mask, an attenuated phase-shift mask, or a chromeless phase-shift mask. In yet another example, the exposure process may be implemented in an off-axis illumination mode.

In some other embodiments, the radiation beam may be directly modulated with a predefined pattern, such as an IC layout, without using a mask (such as using a digital pattern generator or direct-write mode, not shown).

In the present embodiment, the radiation beam is an EUV radiation, and the exposure process is performed in an EUV lithography system, such as the EUV lithography system. In some embodiments, the exposure threshold of the top photoresist layer 220 and the bottom photoresist layer 210 may be lower than 20 mJ/cm². Accordingly, the exposure process may be implemented with the dose less than 20 mJ/cm².

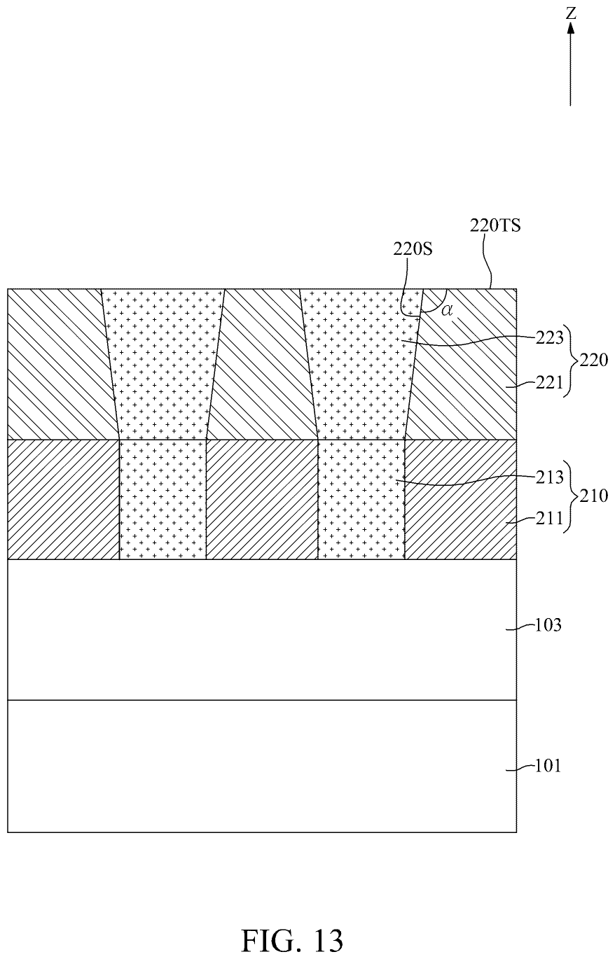

With reference to FIGS. 1 and 13, at step S17, a post-exposure baking process may be performed to the top photoresist layer 220 and the bottom photoresist layer 210.

With reference to FIG. 13, the post-exposure baking (PEB) process may be performed in order to assist in the generating, dispersing, and reacting of the acid generated from the EUV radiation (as described in FIG. 12) upon the photo acid generator 409 of the top photoresist layer 220 and the bottom photoresist layer 210 during the exposure process. Such assistance helps to create or enhance chemical reactions which generate chemical differences between the exposed portions 213, 223 and the un-exposed portions 211, 221. These chemical differences also cause difference in the solubility between the exposed portions 213, 223 and the un-exposed portions 211, 221. In some embodiments, the post-exposure baking may be performed in a thermal chamber at temperature ranging between about 120° C. to about 160° C.

Due to acid diffusion and/or reflow during the post-exposure baking process, the profile of the un-exposed portion 221 of the top photoresist layer 220 may become worse. In other words, the sidewalls 220S of the un-exposed portion 221 may be slanted. The slanted profile may affect the profile of the underlying layer to be patterned in the following process. For example, in the current stage, the angle α between the slanted sidewalls 220S of the un-exposed portion 221 and the top surface 220TS of the top photoresist layer 220 may be greater than 90 degrees, greater than 95 degrees, or greater than 100 degrees.

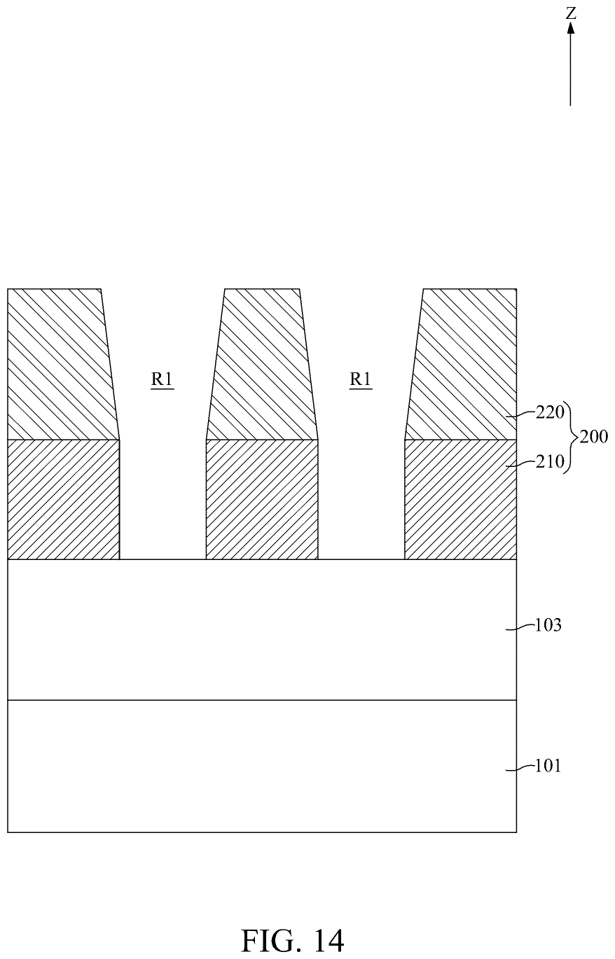

With reference to FIGS. 1 and 14, at step S19, a developing process may be performed to remove the exposed portions 213, 223 of the bottom photoresist layer 210 and the top photoresist layer 220 to form a recess R1 exposing the under layer 103.

With reference to FIG. 14, a developing process may be performed on the top photoresist layer 220 and the bottom photoresist layer 210 using a developer to remove the exposed portions 213, 223. In some embodiments, the developer may contain tetramethyl ammonium hydroxide (TMAH). The exposed portions 213, 223, being soluble in the developer, may be removed during the developing process. The unexposed portions 211, 221 may remain intact after the developing process. As a result, the recess R1 may be formed in the regions previously occupied by the exposed portions 213, 223.

With reference to FIGS. 1, 15, and 16, at step S21, a layer of spacer material 710 may be conformally formed on the top photoresist layer 220, the bottom photoresist layer 210, and the under layer 103, and within the recess R1, and a thermal treatment may be performed to expand the top photoresist layer 220.

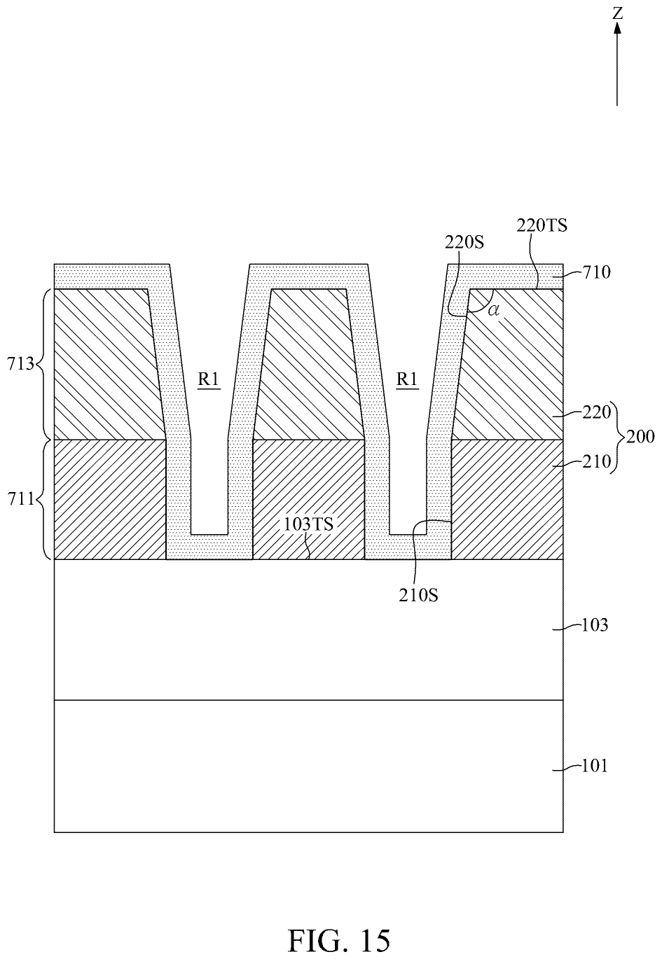

With reference to FIG. 15, the layer of spacer material 710 may be formed within the recess R1, conformally covering the top surface 220TS of the top photoresist layer 220, the sidewalls 220S of the top photoresist layer 220, the sidewalls 210S of the bottom photoresist layer 210, and the top surface 103TS of the underlying layer 103. At this stage, the bottom lateral portion 711 of the layer of spacer material 710, which is disposed on the sidewalls 210S of the bottom photoresist layer 210, may be vertical (with respect to the top surface 103TS of the under layer 103). The top lateral portion 713 of the layer of spacer material 710, which is disposed on the sidewalls 220S of the top photoresist layer 220, may be slanted.

In some embodiments, the spacer material 710 may be, for example, a material having etching selectivity to the bottom photoresist layer 210, the top photoresist layer 220, and/or the under layer 103. In some embodiments, the spacer material 710 may be, for example, silicon oxide, silicon nitride, silicon oxynitride, silicon nitride oxide, or other applicable materials. In some embodiments, the layer of spacer material 710 may be formed by, for example, atomic layer deposition, chemical vapor deposition, physical vapor deposition, or other applicable deposition processes.

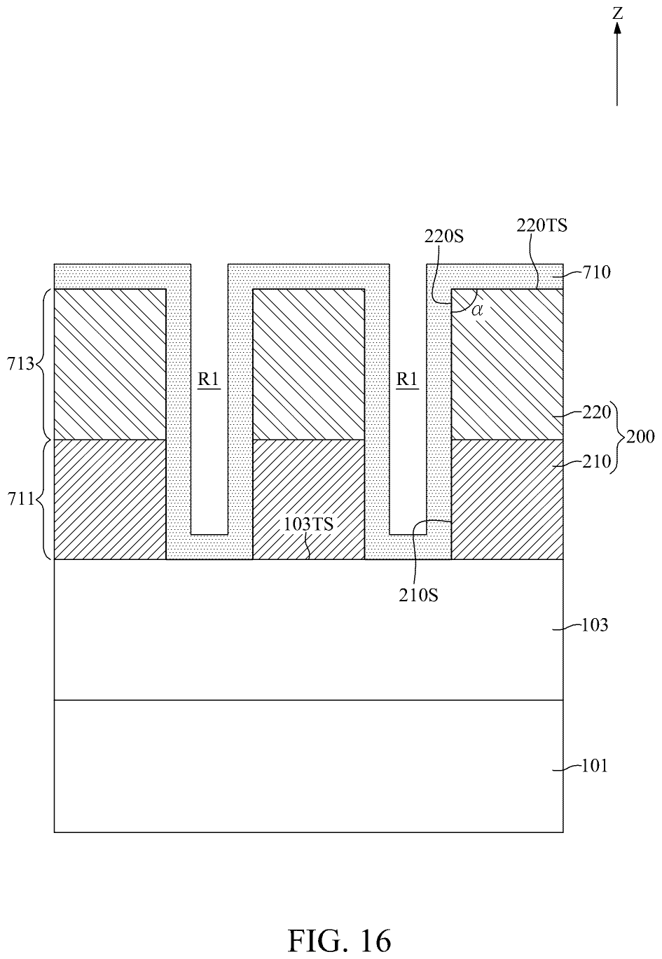

With reference to FIG. 16, the thermal treatment may be performed to induce the expansion of the top photoresist layer 220. Due to the greater CTE of the top photoresist layer 220, the dimension (or width) of the top photoresist layer 220 may be expanded so as to compensate for the slanted sidewalls 220S of the top photoresist layer 220. That is, the sidewalls 220S of the top photoresist layer 220 may become vertical after the thermal treatment. Accordingly, the top lateral portion 713 disposed on the sidewalls 220S of the top photoresist layer 220 may become vertical. In some embodiments, the angle α between the vertical sidewalls 220S of the top photoresist layer 220 and the top surface 220TS of the top photoresist layer 220 may be 90 degrees.

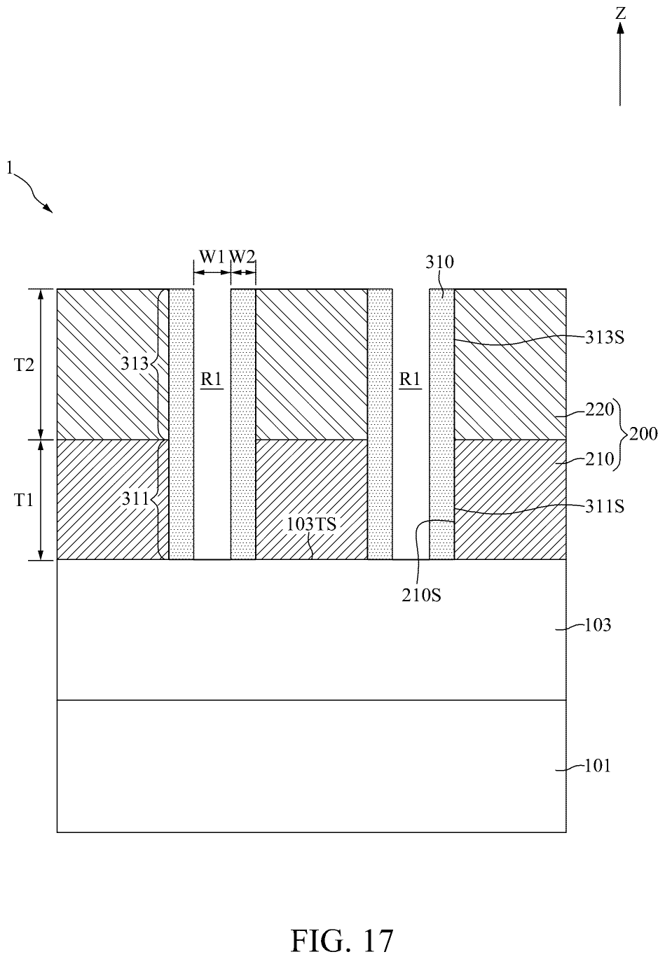

With reference to FIGS. 1 and 17, at step S23, an etching process may be performed to turn the layer of spacer material 710 into a plurality of spacers 310.

With reference to FIG. 17, the etching process may be performed to remove the spacer material 710 formed on the top surface 220TS of the top photoresist layer 220 and on the under layer 103. The remaining spacer material 710 may be referred to as the plurality of spacers 310. In some embodiments, the etching process may be an anisotropic etching process such as an anisotropic dry etching process.

For brevity, clarity, and convenience of description, only one spacer 310 is described. The spacer 310 may include a bottom lateral portion 311 and a top lateral portion 313. The bottom lateral portion 311 may be disposed on the under layer 103 and disposed against the bottom photoresist layer 210. The top lateral portion 313 may be disposed on the bottom lateral portion 311. In some embodiments, the spacer 310 may have a rectangular cross-sectional profile. Both the bottom lateral portion 311 and the top lateral portion 313 have a rectangular cross-sectional profile. In some embodiments, the thickness T2 of the top lateral portion 313 may be greater than the thickness T1 of the bottom lateral portion 311. In some embodiments, the sidewall 313S of the top lateral portion 313 may be vertical. In some embodiments, the sidewall 311S of the bottom lateral portion 311 may be vertical.

In some embodiments, the width ratio of the width W1 of the recess R1 to the width W2 of the spacer 310 may be between about 1.5 and about 0.5, between about 1.3 and about 0.8, or between about 1.1 and about 0.9.

One aspect of the present disclosure provides a photoresist structure including a bottom photoresist layer; a top photoresist layer positioned on the bottom photoresist layer. A coefficient of thermal expansion of the top photoresist layer is greater than a coefficient of thermal expansion of the bottom photoresist layer.

One aspect of the present disclosure provides a semiconductor device including a substrate; an under layer; a bottom photoresist layer positioned on the under layer; a top photoresist layer positioned on the bottom photoresist layer; a recess positioned penetrating the top photoresist layer and the bottom photoresist layer and exposing the under layer; a spacer positioned within the recess and on sidewalls of the bottom photoresist layer and the top photoresist layer. The spacer includes a rectangular cross-sectional profile.

Another aspect of the present disclosure provides a method for fabricating a semiconductor device including providing a substrate, forming an under layer on the substrate, and forming a bottom photoresist layer on the under layer; forming a top photoresist layer on the bottom photoresist layer, wherein a coefficient of thermal expansion of the top photoresist layer is greater than a coefficient of thermal expansion of the bottom photoresist layer; performing an exposure process to form un-exposed portions and exposed portions of the bottom photoresist layer and the top photoresist layer; performing a post-exposure baking process to the bottom photoresist layer and the top photoresist layer; performing a developing process to remove the exposed portions of the bottom photoresist layer and the top photoresist layer and form a recess exposing the under layer; conformally forming a layer of spacer material on sidewalls of the top photoresist layer and the bottom photoresist layer, on a top surface of the top photoresist layer, and on a top surface of the under layer; performing a thermal treatment to expand the top photoresist layer; and performing an etching process to partially remove the layer of spacer material and form a spacer on the sidewalls of the top photoresist layer and the bottom photoresist layer.

The design of the semiconductor device described in this disclosure allows for an improved profile of the plurality of spacers 310 by employing a top photoresist layer 220 with a higher coefficient of thermal expansion (CTE). Consequently, the profile of the underlying layer 103, which is patterned using the plurality of spacers 310 as masks in subsequent processes, may also be enhanced, thereby reducing defects during the fabrication of the semiconductor device 1.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A photoresist structure, comprising:
a bottom photoresist layer; and
a top photoresist layer positioned on the bottom photoresist layer;
wherein a coefficient of thermal expansion of the top photoresist layer is greater than a coefficient of thermal expansion of the bottom photoresist layer.

2. The photoresist structure of claim 1, wherein a ratio of the coefficient of thermal expansion of the top photoresist layer to the coefficient of thermal expansion of the bottom photoresist layer is between about 2.0 and about 1.1.

3. The photoresist structure of claim 1, wherein a thickness of the bottom photoresist layer is greater than a thickness of the bottom photoresist layer.

4. The photoresist structure of claim 3, wherein the top photoresist layer and the bottom photoresist layer comprise the same composition.

5. The photoresist structure of claim 1, wherein the bottom photoresist layer comprises a core polymer, a blocking group, and a photo acid generator.

6. The photoresist structure of claim 5, wherein the core polymer comprises a poly(norbornene)-co-malaic anhydride polymer, a polyhydroxystyrene polymer, or an acrylate-based polymer.

7. The photoresist structure of claim 5, wherein the blocking group comprises t-butoxy-cardbonyl group.

8. The photoresist structure of claim 5, wherein the photo acid generator comprises a sulfonium cation and an anion.

9. The photoresist structure of claim 5, wherein the bottom photoresist layer further comprises a sensitizer.

10. The photoresist structure of claim 9, wherein the sensitizer is mixed with the core polymer and the photo acid generator.

11. The photoresist structure of claim 9, wherein the sensitizer is bonded to the core polymer or the photo acid generator.

12. The photoresist structure of claim 9, wherein the sensitizer comprises a heterocyclic ring that comprises at least one nitrogen atom and at least one double bond.

13. A semiconductor device, comprising:
a substrate;
an under layer;
a bottom photoresist layer positioned on the under layer;
a top photoresist layer positioned on the bottom photoresist layer;
a recess positioned penetrating the top photoresist layer and the bottom photoresist layer and exposing the under layer; and
a spacer positioned within the recess and on sidewalls of the bottom photoresist layer and the top photoresist layer;
wherein the spacer comprises a rectangular cross-sectional profile.

14. The semiconductor device of claim 13, wherein a coefficient of thermal expansion of the top photoresist layer is greater than a coefficient of thermal expansion of the bottom photoresist layer.

15. The semiconductor device of claim 14, wherein an angle between the top surface of the top photoresist layer and the sidewall of the top photoresist layer is 90 degrees.

16. The semiconductor device of claim 14, wherein a thickness of the bottom photoresist layer is greater than a thickness of the bottom photoresist layer.

17. The semiconductor device of claim 14, wherein a ratio of the coefficient of thermal expansion of the top photoresist layer to the coefficient of thermal expansion of the bottom photoresist layer is between about 2.0 and about 1.1.

18. The semiconductor device of claim 14, wherein the top photoresist layer and the bottom photoresist layer comprise the same composition.

19. The semiconductor device of claim 14, wherein a width ratio of a width of the recess to a width of the spacer is between about 1.5 and about 0.5.
